(19) United States
(12) Patent Application Publication
(10) Pub. No.: US 2025/0236175 A1
(43) Pub. Date: Jul. 24, 2025

(54) ACTIVE SOUND EFFECT GENERATING DEVICE AND ACTIVE SOUND EFFECT GENERATING METHOD

(71) Applicant: HONDA MOTOR CO., LTD., TOKYO (JP)

(72) Inventors: Takanori NIIKURA, TOKYO (JP); Yuma KAEDE, TOKYO (JP)

(21) Appl. No.: 19/033,684

(22) Filed: Jan. 22, 2025

(30) Foreign Application Priority Data
Jan. 23, 2024 (JP) 2024-008173
Dec. 19, 2024 (JP) 2024-224109

(51) Int. Cl. B60K 35/26; G01R 31/382

(52) U.S. Cl. CPC B60K 35/26; G01R 31/382

(57) ABSTRACT

An active sound effect generating device for causing a speaker to output a sound effect into a cabin of a vehicle driven by an electric motor includes a signal generating unit configured to generate a first sound effect signal that is a signal for causing the speaker to output the sound effect, a second gain setting unit configured to set a gain according to the amount of regeneration of the electric motor, and an output unit configured to output to the speaker a second sound effect signal generated by multiplying the first sound effect signal by the gain.

### CROSS-REFERENCE TO RELATED APPLICATIONS

This application is based upon and claims the benefit of priority from Japanese Patent Application No. 2024-008173 filed on Jan. 23, 2024 and Japanese Patent Application No. 2024-224109 filed on Dec. 19, 2024, the contents of which are incorporated herein by reference.

### BACKGROUND OF THE INVENTION

### Field of the Invention

The present disclosure relates to an active sound effect generating device and an active sound effect generating method.

### Description of the Related Art

JP 6371328 B2 discloses an active sound effect generating device that generates sound effects through a speaker into a cabin of a vehicle equipped with an electric motor.

### SUMMARY OF THE INVENTION

Better active sound effect generating devices and active sound effect generating methods are awaited.

An object of the present invention is to solve the aforementioned problem.

A first aspect of the present disclosure is an active sound effect generating device for causing a speaker to output a sound effect into a cabin of a vehicle driven by an electric motor, the active sound effect generating device including a signal generating unit configured to generate a first sound effect signal that is a signal for causing the speaker to output the sound effect, a gain setting unit configured to set a gain according to the amount of regeneration of the electric motor, and an output unit configured to output to the speaker a second sound effect signal generated by multiplying the first sound effect signal by the gain.

A second aspect of the present disclosure is an active sound effect generating method for causing a speaker to output a sound effect into a cabin of a vehicle driven by an electric motor, the active sound effect generating method including: generating a first sound effect signal that is a signal for causing the speaker to output the sound effect; setting a gain according to the amount of regeneration of the electric motor; and outputting to the speaker a second sound effect signal generated by multiplying the first sound effect signal by the gain.

The present invention can provide a better active sound effect generating device and method.

The above and other objects, features, and advantages of the present invention will become more apparent from the following description when taken in conjunction with the accompanying drawings, in which a preferred embodiment of the present invention is shown by way of illustrative example.

### BRIEF DESCRIPTION OF THE DRAWINGS

FIG. 1 is a block diagram illustrating the configuration of an active sound effect generator in one embodiment;

FIG. 2 is an image diagram showing a frequency band of link sound and a frequency band of background sound;

FIG. 3 is a graph showing frequency components of an electric motor sound and frequency components of a synthesized sound;

FIG. 4 is a block diagram showing the configuration of a first link-sound signal generating unit according to one embodiment;

FIG. 5 is a map of gains according to one embodiment;

FIG. 6 is a map of gains according to one embodiment;

FIG. 7 is a map of gains according to one embodiment;

FIG. 8 is a map of gains according to one embodiment;

FIG. 9 is a map of gains according to one embodiment;

FIG. 10 is a block diagram showing the configuration of a first background-sound signal generating unit according to one embodiment; and

FIG. 11 is a flowchart of a sound effect generating process performed in the active sound effect generating device according to one embodiment.

### DETAILED DESCRIPTION OF THE INVENTION

In a case of a vehicle having an engine as a driving source, engine braking may be used when the vehicle is traveling on a downhill gradient road surface. When the engine braking is applied, the engine speed increases and the engine sound echoing in the cabin becomes loud.

In a case of a vehicle having an electric motor as the driving source, regenerative braking of the electric motor is used instead of engine braking. When regenerative braking is applied, the sound does not echo as loud as the engine sound in the vehicle, and thus an occupant is less likely to recognize that regenerative braking is engaged.

The active sound effect generating device of the present disclosure can make an occupant recognize that the regenerative braking is applied.

### ONE EMBODIMENT

### [Configuration of Active Sound Effect Generating Device]

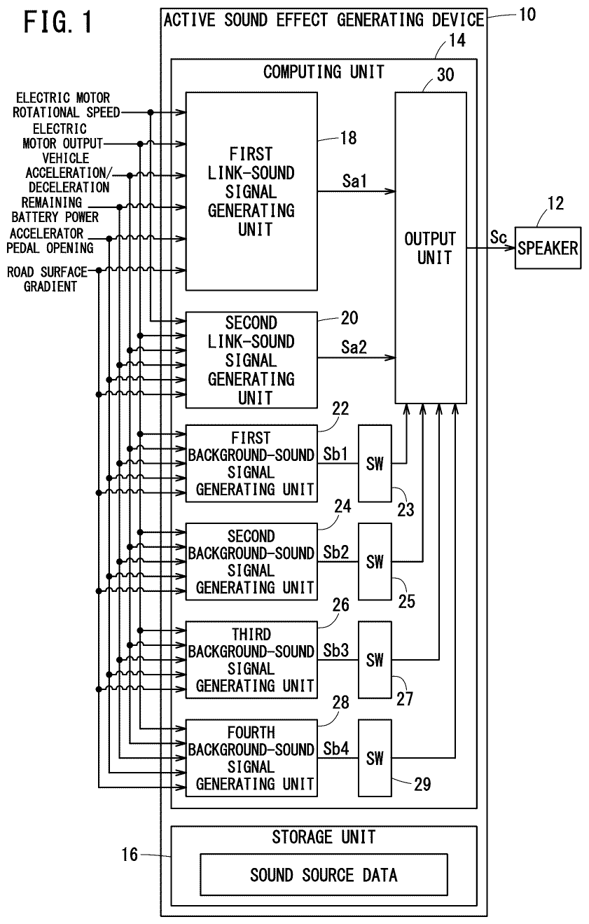

FIG. 1 is a block diagram showing the configuration of an active sound effect generating device 10 according to one embodiment. The active sound effect generating device 10 is installed in a vehicle driven by an electric motor. Vehicles driven by the electric motor are BEVs (Battery Electric Vehicles), HEVs (Hybrid Electric Vehicles), PHEVs (plug-in Hybrid Electric Vehicles), FCEVs (Fuel Cell Electric Vehicles), etc. In the following, vehicles driven by electric motors are referred to as electric vehicles.

The active sound effect generating device 10 is a device that outputs a sound effect that varies according to the rotational speed of the electric motor, from a speaker 12 provided in the cabin of the electric vehicle. The sound effect increases the attractiveness of an electric vehicle to occupants.

The active sound effect generating device 10 includes a computing unit 14 and a storage unit 16. The computing unit 14 is a processor such as a CPU (Central Processing Unit), a GPU (Graphics Processing Unit), or the like.

The computing unit 14 functions as a first link-sound signal generating unit 18, a second link-sound signal generating unit 20, a first background-sound signal generating unit 22, a second background-sound signal generating unit 24, a third background-sound signal generating unit 26, a fourth background-sound signal generating unit 28, and an output unit 30. The first link-sound signal generating unit 18, the second link-sound signal generating unit 20, the first background-sound signal generating unit 22, the second background-sound signal generating unit 24, the third background-sound signal generating unit 26, the fourth background-sound signal generating unit 28, and the output unit 30 are realized by the computing unit 14 executing programs stored in the storage unit 16.

At least part of the first link-sound signal generating unit 18, the second link-sound signal generating unit 20, the first background-sound signal generating unit 22, the second background-sound signal generating unit 24, the third background-sound signal generating unit 26, the fourth background-sound signal generating unit 28, and the output unit 30 may be realized by an integrated circuit such as an ASIC (Application Specific Integrated Circuit), an FPGA (Field-Programmable Gate Array), or the like. At least part of the first link-sound signal generating unit 18, the second link-sound signal generating unit 20, the first background-sound signal generating unit 22, the second background-sound signal generating unit 24, the third background-sound signal generating unit 26, the fourth background-sound signal generating unit 28, and the output unit 30 may be realized by an electronic circuit including a discrete device.

The storage unit 16 is composed of a volatile memory (not shown) and a non-volatile memory (not shown), which are computer-readable storage media. The volatile memory is, for example, RAM (Random Access Memory) or the like. The nonvolatile memory is, for example, ROM (Read Only Memory), flash memory, or the like. Data or the like are stored, for example, in volatile memory. Programs, tables, maps, or the like are stored, for example, in non-volatile memory.

At least part of the storage unit 16 may be provided in the above-mentioned processor, integrated circuit, or the like. At least part of the storage unit 16 may be installed in a device connected to the active sound effect generating device 10 through a network.

The storage unit 16 stores sound source data. The sound source data is information of a sound composed of a plurality of frequency components in a first frequency band. In the following, a sound composed of a plurality of frequency components in the first frequency band may be described as a sound source. The sound source data is digital data sampled at a predetermined sampling period. The sound source data has data that has a predetermined playback time when the sound source is played at a playback speed of 1×. The first frequency band is, for example, 650 Hz to 950 Hz, and its center frequency is 800 Hz. The first frequency band is not limited to the frequency band from 650 Hz to 950 Hz but may be another frequency band. The sound source may contain frequency components in an unbiased manner over the entire first frequency band. The sound pressure (amplitude) of each frequency component contained in the sound source may be equal to each other.

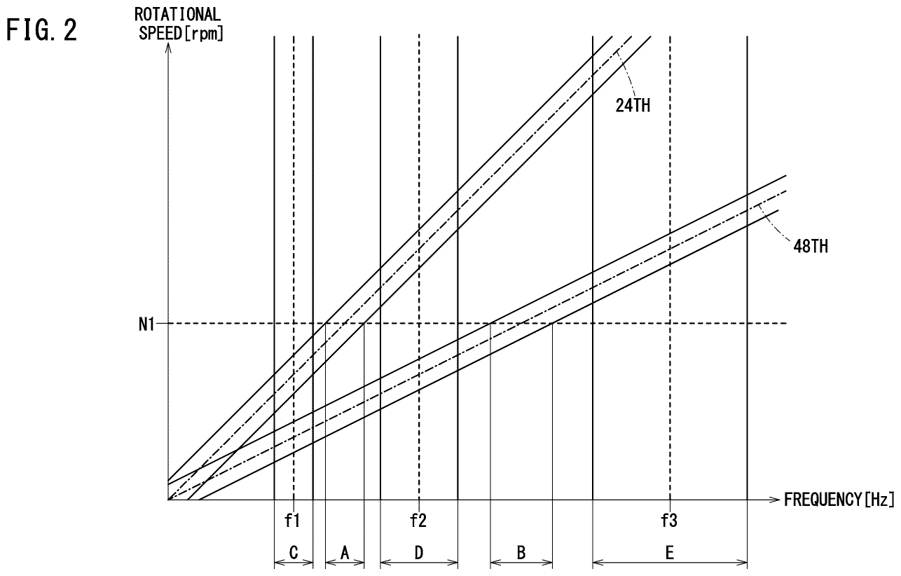

The active sound effect generating device 10 generates a link-sound signal, which is an electric signal that causes the speaker 12 to output a link sound that changes in conjunction with the variation in the rotational speed of the electric motor. The active sound effect generating device 10 generates a background-sound signal, which is an electric signal that causes the speaker 12 to output a background sound that is not linked to the variation in the rotational speed of the electric motor. FIG. 2 is an image diagram showing a frequency band of link sound and a frequency band of background sound.

The first link-sound signal generating unit 18 generates a first link-sound signal Sa1. The first link-sound signal Sa1 is a sound signal composed of a plurality of frequency components in a frequency band that has a predetermined range centered on the 24th frequency of the rotational speed of the electric motor. The frequency band having the predetermined range centered on the 24th frequency of the rotational speed of the electric motor is shown as band A in FIG. 2.

The second link-sound signal generating unit 20 generates a second link-sound signal Sa2. The second link-sound signal Sa2 is a sound signal composed of a plurality of frequency components in a frequency band that has a predetermined range centered on the 48th frequency of the rotational speed of the electric motor. The frequency band having the predetermined range centered on the 48th frequency of the rotational speed of the electric motor is shown as band B in FIG. 2.

The first background-sound signal generating unit 22 generates a first background-sound signal Sb1. The first background-sound signal Sb1 is a sound signal composed of a plurality of frequency components in a frequency band having a predetermined range centered on a frequency f1. The frequency band having the predetermined range centered on the frequency f1 is shown as band C in FIG. 2. A first selection switch 23 switches between a state in which the first background-sound signal Sb1 is output to the output unit 30 and a state in which the first background-sound signal Sb1 is not output to the output unit 30. In the present embodiment, the state in which the first background-sound signal Sb1 is output to the output unit 30 has been selected by the first selection switch 23.

The second background-sound signal generating unit 24 generates a second background-sound signal Sb2. The second background-sound signal Sb2 is a sound signal composed of a plurality of frequency components in a frequency band having a predetermined range centered on a frequency f2. The frequency band having the predetermined range centered on the frequency f2 is shown as band D in FIG. 2. The second selection switch 25 switches between a state in which the second background-sound signal Sb2 is output to the output unit 30 and a state in which the second background-sound signal Sb2 is not output to the output unit 30. In the present embodiment, the state in which the second background-sound signal Sb2 is output to the output unit 30 has been selected by the second selection switch 25.

The third background-sound signal generating unit 26 generates a third background-sound signal Sb3. The third background-sound signal Sb3 is a sound signal composed of a plurality of frequency components in a frequency band having a predetermined range centered on a frequency f3. The frequency band having the predetermined range centered on the frequency f3 is shown as band E in FIG. 2. The third selection switch 27 switches between a state in which the third background-sound signal Sb3 is output to the output unit 30 and a state in which the third background-sound signal Sb3 is not output to the output unit 30. In the present embodiment, the state in which the third background-sound signal Sb3 is output to the output unit 30 has been selected by the third selection switch 27.

The fourth background-sound signal generating unit 28 generates a fourth background-sound signal Sb4. The fourth background-sound signal Sb4 is a sound signal composed of a plurality of frequency components in a frequency band having a predetermined range centered on a frequency f4. A frequency band having a predetermined range centered on the frequency f4 is not shown in FIG. 2. The fourth selection switch 29 switches between a state in which the fourth background-sound signal Sb4 is output to the output unit 30 and a state in which the fourth background-sound signal Sb4 is not output to the output unit 30. In the present embodiment, the state in which the fourth background-sound signal Sb4 is not output to the output unit 30 has been selected by the fourth selection switch 29.

The output unit 30 generates a sound effect signal Sc by synthesizing the first link-sound signal Sa1, the second link-sound signal Sa2, the first background-sound signal Sb1, the second background-sound signal Sb2, the third background-sound signal Sb3, and the fourth background-sound signal Sb4. In this embodiment, since the fourth background-sound signal Sb4 is not output to the output unit 30, in practice, the output unit 30 generates the sound effect signal Sc by synthesizing the first link-sound signal Sa1, the second link-sound signal Sa2, the first background-sound signal Sb1, the second background-sound signal Sb2, and the third background-sound signal Sb3. The output unit 30 outputs the generated sound effect signal Sc to the speaker 12. The speaker 12 generates a sound effect in the cabin in accordance with the sound effect signal Sc.

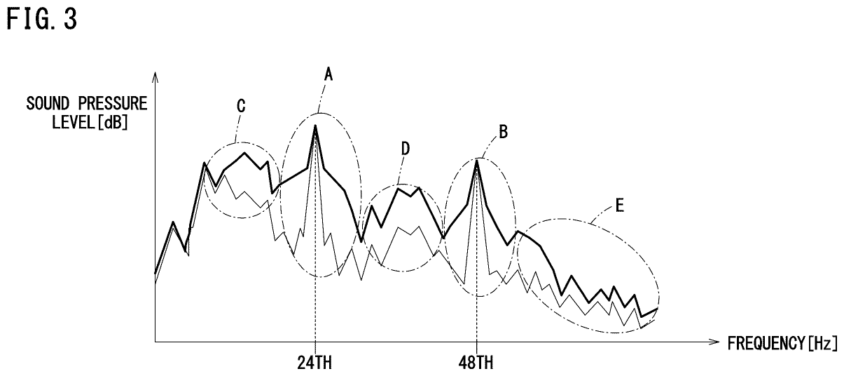

FIG. 3 is a graph showing frequency components of an electric motor sound and frequency components of a synthesized sound. The synthesized sound is a synthesized sound of the electric motor sound and the sound effect signal Sc generated from the speaker 12. A thin line graph in FIG. 3 indicates the frequency components of the electric motor sound whereas a thick line graph indicates the frequency components of the synthesized sound. FIG. 3 shows the frequency components when the electric motor is at the rotational speed N1 (see FIG. 2). The electric motor sound is not limited to the sound generated by the electric motor itself. The electric motor sound may include, for example, a sound generated by a gear rotating in synchronization with the electric motor.

As shown in FIG. 3, the sound pressure levels of the 24th frequency component and the 48th frequency component stand out compared to the sound pressure levels of the other frequency components. Therefore, the sound of the 24th frequency component and the sound of the 48th frequency component are heard distinctively by the occupant in the vehicle, giving the occupant a sense of discomfort. Therefore, the sound pressure level of the components in the frequency band having the predetermined range centered on the 24th frequency is increased by generating the first link-sound signal Sa1 from the speaker 12 (see the portion indicated by A in FIG. 3). Therefore, the sound pressure level of the components in the frequency band having the predetermined range centered on the 48th frequency is increased by generating the second link-sound signal Sa2 (see the portion indicated by B in FIG. 3). In this way, a synthesized sound can be generated that is linked to the variation in the rotational speed of the electric motor and alleviates the prominence of the sound of the 24th frequency component and the sound of the 48th frequency component.

The order of the frequency component of the outstanding sound pressure level varies depending on electric motor specifications, transmission specifications, powertrain specifications, or the like. Therefore, the order of the frequency component of the outstanding sound pressure level is not limited to the 24th or 48th. In addition, the number of points where the sound pressure levels stand out varies depending on the electric motor specifications, the transmission specifications, the powertrain specifications, or the like. Therefore, the points where the sound pressure levels stand out are not limited to two points (24th, 48th). For example, when the sound pressure levels stand out at three points, a third link-sound signal generator (not shown) may be provided in the active sound effect generating device 10 in addition to the first link-sound signal generating unit 18 and the second link-sound signal generating unit 20 shown in FIG. 1.

In addition, a vehicle body may resonate with the electric motor sound, and the sound pressure level of the component of the resonant frequency of the vehicle body may stand out from the sound pressure levels of the other frequency components. Therefore, the first background-sound signal Sb1, the second background-sound signal Sb2, and the third background-sound signal Sb3 are generated from the speaker 12, thereby increasing the sound pressure level of the components of a frequency band having a predetermined range centered on the resonance frequency of the vehicle body (see the portions indicated by C, D, and E in FIG. 2). Thus, the synthesized sound can be obtained where the prominence of the resonance sound has been alleviated.

Because the resonance frequency varies with the vehicle body, the center frequencies of the first background-sound signal Sb1, the second background-sound signal Sb2, and the third background-sound signal Sb3 are adjusted and determined for each vehicle body. Further, because the number of resonant frequencies also varies with the vehicle body, the background sound is not limited to three types that are the first background-sound signal Sb1, the second background-sound signal Sb2 and the third background-sound signal Sb3 but may be two or less types of background sound and four or more types of background sound. For example, when the types of background sound are two, it is ensured that a state in which the third background-sound signal Sb3 is not output to the output unit 30 is selected by the third selection switch 27 shown in FIG. 1. For example, when the types of background sound are four, it is ensured that the fourth selection switch 29 shown in FIG. 1 selects the state in which the fourth background-sound signal Sb4 is output to the output unit 30. For example, when the types of background sound are five, a fifth background-sound signal generating unit (not shown) may be provided in the active sound effect generating device 10 in addition to the first background-sound signal generating unit 22, the second background-sound signal generating unit 24, the third background-sound signal generating unit 26, and the fourth background-sound signal generating unit 28 shown in FIG. 1.

### [Configuration of Link-Sound Signal Generating Unit]

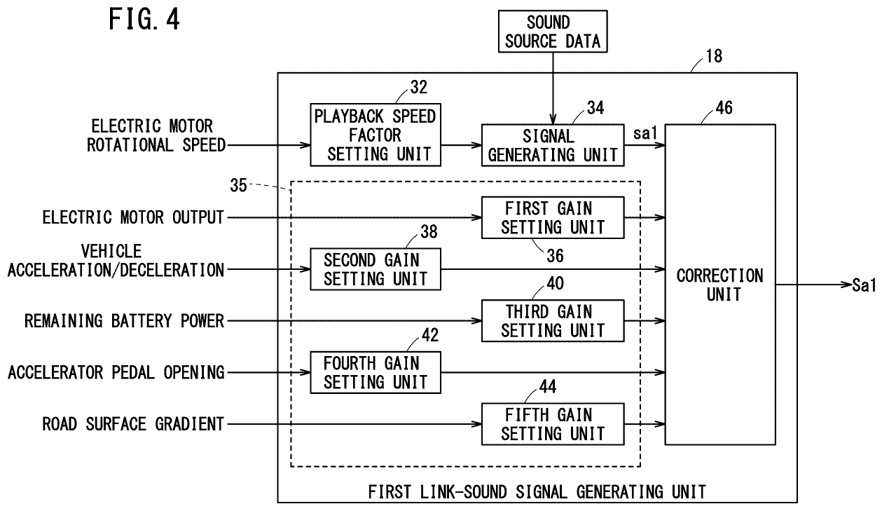

FIG. 4 is a block diagram showing the configuration of the first link-sound signal generating unit 18 according to the present embodiment. The first link-sound signal generating unit 18 includes a playback speed factor setting unit 32, a signal generating unit 34, a gain setting unit 35, and a correction unit 46.

The playback speed factor setting unit 32 sets a playback speed factor α of the sound source data. The playback speed factor α is obtained by the following formula (1) according to the rotational speed N [rpm] of the electric motor. In the formula (1), fa is the center frequency [Hz] of the first frequency band of the aforementioned sound source.

$$α = \frac{N \times 24}{60 \times f a} \qquad ( 1 )$$

The signal generating unit 34 generates a first link-sound signal sa1 from the sound source data. The first link-sound signal sa1 is a signal whose amplitude has not yet been corrected. The amplitude of the first link-sound signal sa1 is corrected in the correction unit 46, which will be described later, to generate the first link-sound signal Sa1. The sound source data is a signal of a sound source consisting of a plurality of frequency components in a first frequency band whose center frequency is fa [Hz]. The first link-sound signal sa1 is a signal of the first link sound composed of a plurality of frequency components in the second frequency band centered on the 24th frequency of the rotational speed of the electric motor. The sound source is played at a times speed, whereby the first link sound is produced. Therefore, the signal generating unit 34 selects a digital signal at intervals of α-1 digital signals from a digital signal sequence of the sound source data and arranges the selected digital signals in chronological order, thereby generating a digital signal sequence of the first link-sound signal sa1. By repeatedly arranging the selected digital signals, it is possible to generate the first link-sound signal sa1 the playback time of which is longer than that of the original sound source data.

The gain setting unit 35 functions as a first gain setting unit 36, a second gain setting unit 38, a third gain setting unit 40, a fourth gain setting unit 42, and a fifth gain setting unit 44.

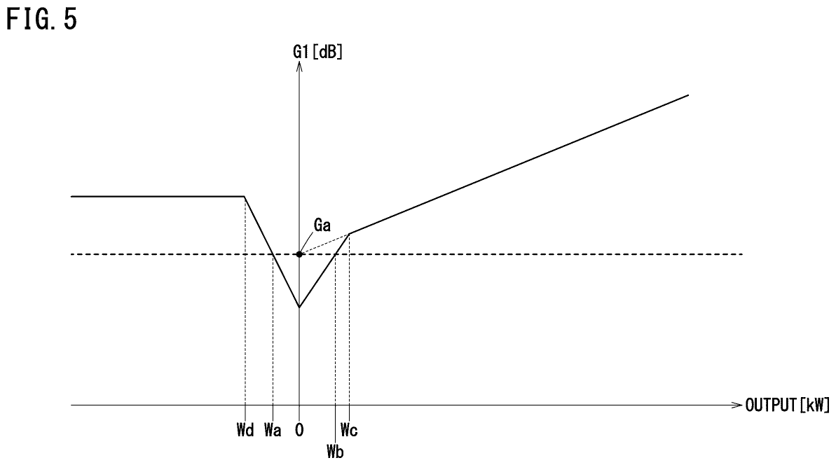

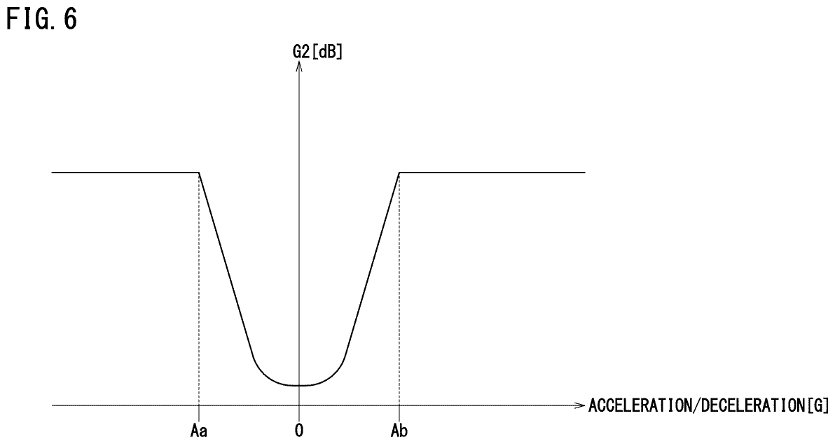

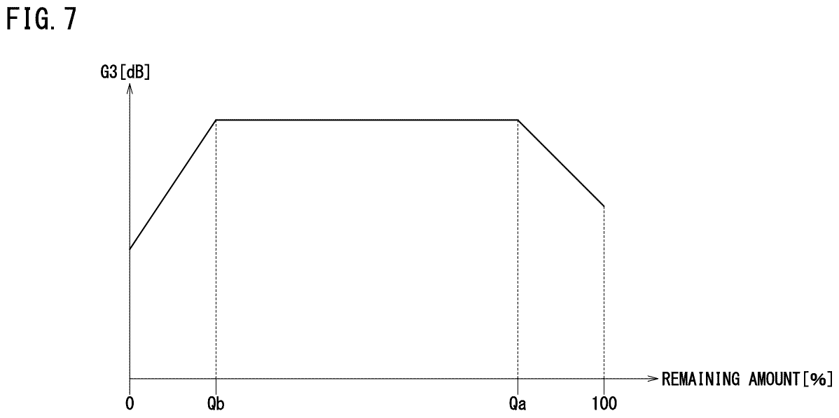

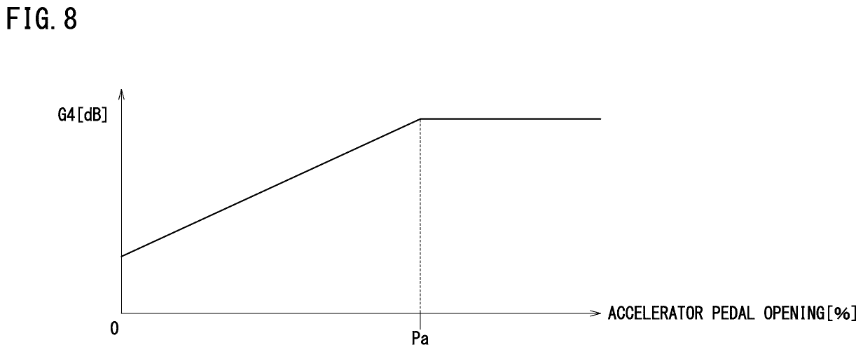

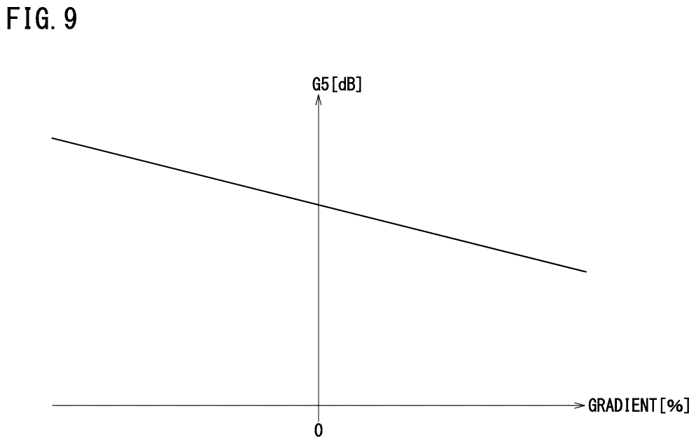

The first gain setting unit 36 sets a gain G1 according to the output of the electric motor. FIG. 5 is a map of the gain G1 in the present embodiment. The second gain setting unit 38 sets a gain G2 according to the acceleration/deceleration of the vehicle. FIG. 6 is a map of the gain G2 in the present embodiment. The third gain setting unit 40 sets a gain G3 according to the remaining battery power. FIG. 7 is a map of the gain G3 in the present embodiment. The battery is charged by the regenerative power when the electric motor is regenerated. The fourth gain setting unit 42 sets a gain G4 according to an accelerator pedal opening. FIG. 8 is a map of the gain G4 in the present embodiment. The fifth gain setting unit 44 sets a gain G5 according to the gradient of the road surface on which the vehicle is traveling. FIG. 9 is a map of the gain G5 in the present embodiment.

The correction unit 46 generates the first link-sound signal Sa1 by multiplying the first link-sound signal sa1 generated in the signal generating unit 34 by the gains G1 to G5. The first link-sound signal sa1 generated in the signal generating unit 34 corresponds to the first sound effect signal of the present invention. The first link-sound signal Sa1 generated in the correction unit 46 corresponds to the second sound effect signal of the present invention.

The second link-sound signal generating unit 20 includes the playback speed factor setting unit 32, the signal generating unit 34, the gain setting unit 35, and the correction unit 46, as the first link-sound signal generating unit 18. The second link-sound signal generating unit 20 is different from the first link-sound signal generating unit 18 in that the playback speed factor x is obtained by the following formula (2) in the playback speed factor setting unit 32, but the other configuration is the same as that of the first link-sound signal generating unit 18.

$$α = \frac{N \times 48}{60 \times f a} \qquad ( 2 )$$

### [Configuration of Background-Sound Signal Generating Unit]

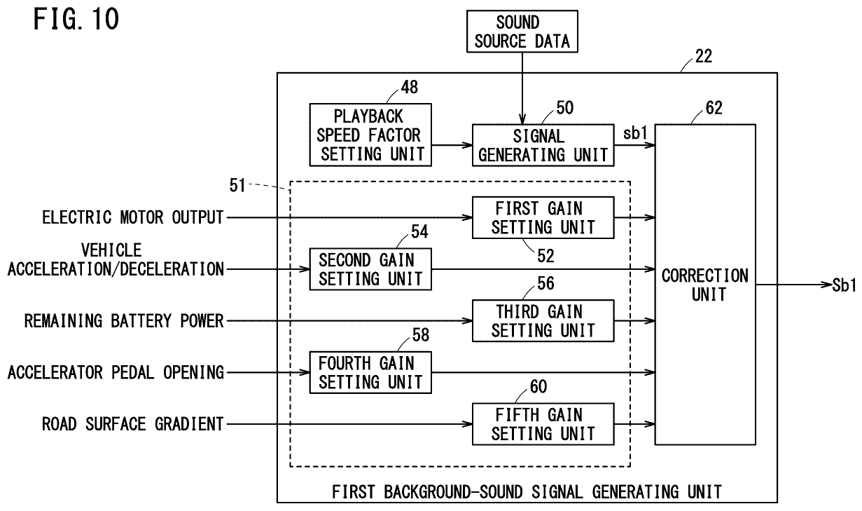

FIG. 10 is a block diagram showing the configuration of a first background-sound signal generating unit 22 according to the present embodiment. The first background-sound signal generating unit 22 includes a playback speed factor setting unit 48, a signal generating unit 50, a gain setting unit 51, and a correction unit 62.

The playback speed factor setting unit 48 sets a playback speed factor α of the sound source data. The playback speed factor α is obtained by the following formula (3) according to the center frequency f1 [Hz] of the first background-sound signal Sb1.

$$β = \frac{f 1}{f a} \qquad ( 3 )$$

The signal generating unit 50 generates a first background-sound signal sb1 from the sound source data. The first background-sound signal sb1 is a signal whose amplitude has not yet been corrected. In the correction unit 62, which will be described later, the amplitude of the first background-sound signal sb1 is corrected to generate the first background-sound signal Sb1. The sound source data is a signal of a sound source consisting of a plurality of frequency components in a first frequency band whose center frequency is fa [Hz]. The first background-sound signal sb1 is a signal of a first background sound composed of a plurality of frequency components in a third frequency band having f1 [Hz] as the center frequency. The first background sound is generated by reproducing the sound source at B-times speed. Therefore, the signal generating unit 50 selects a digital signal at intervals of β-1 digital signals from a digital signal sequence of the sound source data and arranges the selected digital signals in chronological order, thereby generating a digital signal sequence of the first background-sound signal sb1. By repeatedly arranging the selected digital signals, it is possible to generate the first background-sound signal sb1 the playback time of which is longer than that of the original source data.

The gain setting unit 51 functions as a first gain setting unit 52, a second gain setting unit 54, a third gain setting unit 56, a fourth gain setting unit 58, and a fifth gain setting unit 60.

The first gain setting unit 52 sets a gain G1 according to the output of the electric motor. The gain G1 is set based on the map of FIG. 5 described above. The second gain setting unit 54 sets a gain G2 according to the acceleration/deceleration of the vehicle. The gain G2 is set based on the map of FIG. 6 described above. The third gain setting unit 56 sets a gain G3 according to the remaining battery power. The gain G3 is set based on the map of FIG. 7 described above. The fourth gain setting unit 58 sets a gain G4 according to the accelerator pedal opening. The gain G4 is set based on the map of FIG. 8 described above. The fifth gain setting unit 60 sets a gain G5 according to the gradient of the road surface on which the vehicle is traveling. The gain G5 is set based on the map of FIG. 9 described above.

The correction unit 62 generates the first background-sound signal Sb1 by multiplying the first background-sound signal sb1 generated in the signal generating unit 50 by the gains G1 to G5. The first background-sound signal sb1 generated in the signal generating unit 50 corresponds to the first sound effect signal of the present invention. The first background-sound signal Sb1 generated in the correction unit 62 corresponds to the second sound effect signal of the present invention.

The second background sound signal generating unit 24 includes the playback speed factor setting unit 48, the signal generating unit 50, the gain setting unit 51, and the correction unit 62, as the first background sound signal generating unit 22. The second background-sound signal generating unit 24 is different from the first background-sound signal generating unit 22 in that the playback speed factor β is obtained by the following formula (4) in the playback speed factor setting unit 48, but the other configuration is the same as that of the first background-sound signal generating unit 22.

$$β = \frac{f 2}{f a} \qquad ( 4 )$$

The third background sound signal generating unit 26 includes the playback speed factor setting unit 48, the signal generating unit 50, the gain setting unit 51, and the correction unit 62, as the first background sound signal generating unit 22. The third background-sound signal generating unit 26 is different from the first background-sound signal generating unit 22 in that the playback speed factor β is obtained by the following formula (5) in the playback speed factor setting unit 48, but the other configuration is the same as that of the first background-sound signal generating unit 22.

$$β = \frac{f 3}{f a} \qquad ( 5 )$$

The fourth background sound signal generating unit 28 includes a playback speed factor setting unit 48, a signal generating unit 50, a gain setting unit 51, and a correction unit 62, similarly to the first background sound signal generating unit 22. The fourth background-sound signal generating unit 28 is different from the first background-sound signal generating unit 22 in that the playback speed factor β is obtained by the following formula (6) in the playback speed factor setting unit 48, but the other configuration is the same as that of the first background-sound signal generating unit 22.

$$β = \frac{f 4}{f a} \qquad ( 6 )$$

### [Gains]

As described above, the first gain setting unit 36 sets the gain G1 according to the output of the electric motor, based on the map of FIG. 5.

As shown in FIG. 5, when the output of the electric motor is equal to or greater than a predetermined output Wa [KW] (Wa<0) and less than a predetermined output Wb [KW] (Wb>0), the gain G1 is set to a value equal to or less than a predetermined gain Ga. When the sound effect signal Sc is equal to or less than the predetermined gain Ga, the sound effect output from the speaker 12 is buried in the noise outside the vehicle and the running sound of the vehicle and is hardly perceived by the occupant in the cabin. Thus, when the vehicle speed is extremely low, it is possible to enhance the quietness in the cabin by making the sound effect imperceptible for the occupant.

As shown in FIG. 5, when the output of the electric motor is equal to or greater than a predetermined output Wc [KW] (Wc>Wb), the gain G1 is set to be larger as the output of the electric motor becomes larger. Thus, the sound pressure of the sound effect increases proportionally with the acceleration of the vehicle, and the occupant can feel the linearity between the vehicle behavior and the sound effect.

As shown in FIG. 5, when the output of the electric motor is equal to or more than the predetermined output Wd [KW] (Wd<Wa) and less than the predetermined output Wa [KW], the gain G1 is set to be larger as the amount of regeneration of the electric motor becomes larger. Thus, the sound pressure of the sound effect increases proportionally with the deceleration of the vehicle, and the occupant can feel the linearity between the vehicle behavior and the sound effect.

As shown in FIG. 5, when the output of the electric motor is less than the predetermined output Wd [KW], the magnitude of the gain G1 is made constant regardless of the amount of regeneration of the electric motor. Thus, the sound pressure of the sound effect does not become too large when the vehicle decelerates, and the sense of discomfort felt by the occupant can be suppressed.

As described above, the second gain setting unit 38 sets the gain G2 according to the acceleration/deceleration of the vehicle based on the map of FIG. 6.

As shown in FIG. 6, when the acceleration/deceleration of the vehicle is equal to or greater than the predetermined acceleration/deceleration Aa [G] (Aa<0) and less than the predetermined acceleration/deceleration Ab [G] (Ab>0), the gain G2 is set to be larger as the acceleration/deceleration of the vehicle moves farther away from 0 [G]. Thus, when the vehicle is in the cruise traveling state, the sound effect can be made smaller to enhance the quietness in the cabin. In addition, when the vehicle behavior changes from the cruise traveling state to the acceleration/deceleration state, the sound pressure of the sound effect can be smoothly changed, and the sense of unity between the vehicle behavior and the sound effect can be given to the occupant.

When the acceleration/deceleration of the vehicle is less than the predetermined acceleration/deceleration Aa [G] or the acceleration/deceleration of the vehicle is greater than or equal to the predetermined acceleration/deceleration Ab [G], the magnitude of the gain G2 is made constant regardless of the acceleration/deceleration of the vehicle. When the acceleration/deceleration of the vehicle is less than a predetermined acceleration/deceleration Aa [G] or the acceleration/deceleration of the vehicle is equal to or greater than Ab [G], the sound pressure of the sound effect changes according to the output of the electric motor regardless of the acceleration/deceleration.

As described above, the third gain setting unit 40 sets the gain G3 according to the remaining battery level based on the map of FIG. 7.

As shown in FIG. 7, the gain G3 when the remaining battery power is equal to or more than a predetermined amount Qa [%] is smaller than the gain G3 when the remaining battery power is less than the predetermined amount Qa [%]. This reduces the sound pressure of the sound effect when the battery is close to full charge. Thus, when the vehicle is decelerating, a difference can be produced between the sound pressure of the sound effect when the electric motor is regenerating and the sound pressure of the sound effect when the electric motor is not regenerating. Therefore, the occupant can be made to recognize that the regeneration of the electric motor is not being performed. When the vehicle accelerates, the remaining battery power decreases, and thus no difference occurs between the sound pressure of the sound effect when the electric motor gives power for traveling and the sound pressure of the sound effect when the electric motor does not give power for traveling.

As shown in FIG. 7, the gain G3 when the remaining battery power is less than a predetermined amount Qb [%] is smaller than the gain G3 when the remaining battery power is equal to or more than the predetermined amount Qb [%]. This reduces the sound pressure of the sound effect when the battery is almost empty. Therefore, the occupant can be made aware that the battery is almost empty.

As described above, the fourth gain setting unit 42 sets the gain G4 according to the accelerator pedal opening based on the map of FIG. 8.

As shown in FIG. 8, when the accelerator pedal opening is less than a predetermined opening Pa [%], the gain G4 is set to be larger as the accelerator pedal opening becomes larger. Thus, the sound pressure of the sound effect increases proportionally with the accelerator pedal opening, and the occupant can feel the linearity between the accelerator pedal operation by the occupant and the sound effect.

As shown in FIG. 8, when the accelerator pedal opening is equal to or larger than the predetermined opening Pa [%], the magnitude of the gain G4 is made constant regardless of the magnitude of the accelerator pedal opening. Thus, the sound pressure of the sound effect does not become too large when the occupant steps on the accelerator pedal, and the sense of discomfort felt by the occupant can be suppressed.

As described above, the fifth gain setting unit 44 sets the gain G5 according to the gradient of the road surface on which the vehicle is traveling based on the map of FIG. 9.

When the road surface has a large uphill gradient, the accelerator pedal opening becomes large. Because the sound pressure of the sound effect increases as the accelerator pedal opening increases, the sound pressure of the sound effect becomes excessive when the vehicle is traveling on an uphill gradient, resulting in that the occupant is given a sense of discomfort. In the present embodiment, as shown in FIG. 9, the gain G5 is set to be smaller as the uphill gradient of the road surface becomes larger. Therefore, even when the vehicle is traveling on an uphill gradient, the sound effect is suppressed from becoming excessive, and a sense of discomfort given to the occupant can be reduced.

When the road surface has a large downhill gradient, the accelerator pedal opening becomes small. Because the sound pressure of the sound effect decreases as the accelerator pedal opening decreases, the sound pressure of the sound effect becomes too low when the vehicle is traveling on a downhill gradient. When the vehicle is traveling on a downhill gradient, the sound pressure of the sound effect becomes too small despite the occurrence of regenerative braking, resulting in that the occupant is given a sense of discomfort. In the present embodiment, as shown in FIG. 9, the gain G5 is set to be smaller as the downhill gradient of the road surface becomes larger. Therefore, even when the vehicle is traveling on a downhill gradient, a case is avoided where the sound effect becomes too small, and a sense of discomfort given to the occupant can be reduced.

### [Sound Effect Generating Process]

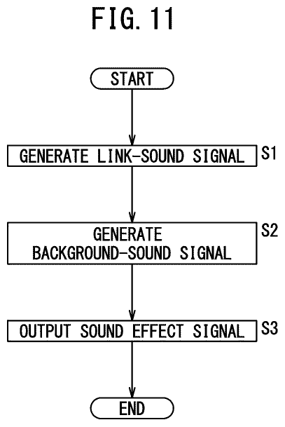

FIG. 11 is a flowchart of a sound effect generating process executed in the active sound effect generating device 10 of the present embodiment. The sound effect generating process is repeatedly executed at a predetermined cycle while the electric vehicle is traveling.

In step S1, the first link-sound signal generating unit 18 generates the first link-sound signal Sa1. The second link-sound signal generating unit 20 generates the second link-sound signal Sa2. Then, the process proceeds to step S2.

In step S2, the first background-sound signal generating unit 22 generates the first background-sound signal Sb1. The second background-sound signal generating unit 24 generates the second background-sound signal Sb2. The third background-sound signal generating unit 26 generates the third background-sound signal Sb3. The fourth background-sound signal generating unit 28 generates the fourth background-sound signal Sb4. Then, the process proceeds to step S3.

In step S3, the output unit 30 generates the sound effect signal Sc. The output unit 30 also outputs the sound effect signal Sc to the speaker 12. In this way, the sound effect generating process is performed.

### OTHER EMBODIMENTS

In one embodiment, in each of the first link-sound signal generating unit 18 and the second link-sound signal generating unit 20, the correction unit 46 multiplies each of the first link-sound signal sa1 and the second link-sound signal sa2 generated by the signal generating unit 34 by the gains G1 to G5 to generate the first link-sound signal Sa1 and the second link-sound signal Sa2. On the other hand, the gain setting unit 35 may set to the gain G a value obtained by multiplying the gains G1 to G5. The correction unit 46 may multiply each of the first and second link-sound signals sa1 and sa2 by the gain G to generate the first and second link-sound signals sa1 and sa2.

In one embodiment, in each of the first background-sound signal generating unit 22, the second background-sound signal generating unit 24, the third background-sound signal generating unit 26, and the fourth background-sound signal generating unit 28, the correction unit 62 multiplies each of the first background-sound signal sb1, the second background-sound signal sb2, the third background-sound signal Sb3, and the fourth background-sound signal Sb4 generated by the signal generating unit 50 by the gains G1 to G5 to generate the first background-sound signal Sb1, the second background-sound signal Sb2, the third background-sound signal Sb3, and the fourth background-sound signal Sb4. On the other hand, the gain setting unit 51 may set the gain G to a value obtained by multiplying the gains G1 to G5. The correction unit 62 may multiply each of the first background-sound signal sb1, the second background-sound signal sb2, the third background-sound signal sb3, and the fourth background-sound signal sb4 by the gain G to generate the first background-sound signal Sb1, the second background-sound signal Sb2, the third background-sound signal Sb3, and the fourth background-sound signal Sb4.

When the vehicle travels on an uphill gradient at the same speed as it travels on the flat ground, the output of the electric motor when traveling on the uphill gradient becomes larger than the output of the electric motor when traveling on the flat ground. When the gain G is set only according to the output of the electric motor, the gain G increases as the uphill gradient of the road surface increases. Therefore, when the vehicle is traveling on an uphill gradient, the sound pressure of the sound effect becomes excessive, causing a sense of discomfort to the occupants.

The gain G is set at least according to the output of the electric motor, the acceleration of the vehicle, and the gradient of the road on which the vehicle is traveling. As shown in FIG. 5, when the output of the electric motor is 0 [KW] or more, the gain G1 increases as the output of the electric motor increases. As shown in FIG. 6, when the acceleration of the vehicle is less than the predetermined acceleration Ab [G], the gain G2 is smaller as the acceleration is smaller. As shown in FIG. 9, the gain G5 is smaller as the uphill gradient of the road becomes larger.

Thus, when the vehicle is cruising at a constant speed on an uphill gradient, the sound effect is suppressed from being excessive and thus the sense of discomfort given to the occupants can be reduced.

With respect to the above embodiments, the following supplementary notes are further disclosed.

### (Supplementary Note 1)

An active sound effect generating device (10) of the present disclosure is an active sound effect generating device for causing a speaker (12) to output a sound effect into a cabin of a vehicle driven by an electric motor and includes a signal generating unit (34) configured to generate a first sound effect signal that is a signal for causing the speaker to output the sound effect, a gain setting unit (35) configured to set a gain according to the amount of regeneration of the electric motor, and an output unit (30) configured to output to the speaker a second sound effect signal generated by multiplying the first sound effect signal by the gain. Thus, the sound effect can be changed according to the amount of regeneration of the electric motor.

### (Supplementary Note 2)

In the active sound effect generating device according to Supplementary note 1, the gain when a remaining amount of the battery of the vehicle charged by regenerative power of the electric motor is equal to or more than a predetermined amount may be smaller than the gain when the remaining amount of the battery is less than the predetermined amount. Thus, the sound effect when the electric motor is undergoing regeneration can be made different from the sound effect when the electric motor is not undergoing regeneration.

### (Supplementary Note 3)

In the active sound effect generating device according to Supplementary note 1, the gain setting unit may set the gain further according to a gradient of a road surface on which the vehicle is traveling. This allows the sound effect to vary according to the gradient of the road surface on which the vehicle is traveling.

### (Supplementary Note 4)

In the active sound effect generating device according to Supplementary note 1, the gain may be larger as the amount of regeneration is larger. Thus, the sound effect can be changed according to the amount of regeneration of the electric motor.

### (Supplementary Note 5)

In the active sound effect generating device according to Supplementary note 1, the gain setting unit may set the gain further according to the deceleration of the vehicle and the gain may be larger as the deceleration is larger. This allows the sound effect to vary according to the deceleration of the vehicle.

### (Supplementary Note 6)

In the active sound effect generating device according to Supplementary note 3, the gain may be smaller as the uphill gradient of the road surface becomes larger whereas the gain may be larger as the downhill gradient of the road surface becomes larger. Thus, the sound pressure of the sound effect can be suppressed from becoming excessive while the vehicle is traveling on an uphill gradient. In addition, it is possible to suppress the sound pressure of the sound effect from becoming too low while the vehicle is traveling on a downhill gradient.

### (Supplementary Note 7)

In the active sound effect generating device according to Supplementary note 1, the gain setting unit may set the gain according to the output of the electric motor, the gradient of the road surface on which the vehicle is traveling, and the acceleration of the vehicle. This adjusts the sound pressure of the sound effect according to the output of the electric motor, the gradient of the road surface, and the acceleration of the vehicle.

### (Supplementary Note 8)

In the active sound effect generating device according to Supplementary note 7, the gain may be larger as the output of the electric motor becomes larger, the gain may be smaller as the uphill gradient of the road surface becomes larger, and the gain may be smaller as the acceleration becomes smaller. Thus, the sound pressure of the sound effect can be suppressed from becoming excessive while the vehicle is traveling on an uphill gradient.

### (Supplementary Note 9)

An active sound effect generating method of the present disclosure is an active sound effect generating method for causing a speaker to output a sound effect into a cabin of a vehicle driven by an electric motor, the active sound effect generating method including generating a first sound effect signal that is a signal for causing the speaker to output the sound effect, setting a gain according to an amount of regeneration of the electric motor; and outputting to the speaker a second sound effect signal generated by multiplying the first sound effect signal by the gain. Thus, the sound effect can be changed according to the amount of regeneration of the electric motor.

Although the present disclosure has been detailed, the present disclosure is not limited to the individual embodiments described above. These embodiments may be variously added, replaced, altered, partially deleted, etc., without departing from the scope of the present disclosure or the intent of the present disclosure as derived from the claims and their equivalents. These embodiments can also be implemented in combination. For example, in the above-described embodiment, the order of the operations and the order of the processes are shown as an example, and are not limited to these. The same applies to the case where numerical values or mathematical expressions are used in the description of the above-described embodiment.

1. An active sound effect generating device for causing a speaker to output a sound effect into a cabin of a vehicle driven by an electric motor, the active sound effect generating device comprising
one or more processors that execute computer-executable instructions stored in a memory,
wherein the one or more processors execute the computer-executable instructions to cause the active sound effect generating device to:
generate a first sound effect signal that is a signal for causing the speaker to output the sound effect;
set a gain according to an amount of regeneration of the electric motor; and
output to the speaker a second sound effect signal generated by multiplying the first sound effect signal by the gain.

2. The active sound effect generating device according to claim 1, wherein
the gain when a remaining amount of a battery of the vehicle charged by regenerative power of the electric motor is equal to or more than a predetermined amount is smaller than the gain when the remaining amount of the battery is less than the predetermined amount.

3. The active sound effect generating device according to claim 1, wherein
the one or more processors execute the computer-executable instructions to cause the active sound effect generating device to set the gain further according to a gradient of a road surface on which the vehicle is traveling.

4. The active sound effect generating device according to claim 1, wherein
as the amount of regeneration is larger, the gain is larger.

5. The active sound effect generating device according to claim 1, wherein
the one or more processors execute the computer-executable instructions to cause the active sound effect generating device to set the gain further according to a deceleration of the vehicle, and
as the deceleration is larger, the gain is larger.

6. The active sound effect generating device according to claim 3, wherein
as an uphill gradient of the road surface becomes larger, the gain is smaller whereas as a downhill gradient of the road surface becomes larger, the gain is larger.

7. The active sound effect generating device according to claim 1, wherein
the one or more processors execute the computer-executable instructions to cause the active sound effect generating device to set the gain according to an output of the electric motor, a gradient of a road surface on which the vehicle is traveling, and an acceleration of the vehicle.

8. The active sound effect generating device according to claim 7, wherein
the gain is larger as the output of the electric motor becomes larger, the gain is smaller as an uphill gradient of the road surface becomes larger, and the gain is smaller as the acceleration becomes smaller.

9. An active sound effect generating method for causing a speaker to output a sound effect into a cabin of a vehicle driven by an electric motor, the active sound effect generating method comprising:
generating a first sound effect signal that is a signal for causing the speaker to output the sound effect;
setting a gain according to an amount of regeneration of the electric motor; and
outputting to the speaker a second sound effect signal generated by multiplying the first sound effect signal by the gain.
